(19) United States
(12) Patent Application Publication
(10) Pub. No.: US 2026/0096241 A1
(43) Pub. Date: Apr. 2, 2026

(54) TANDEM SOLAR CELL

(71) Applicant: JUSUNG ENGINEERING CO., LTD., Gwangju-Si, Gyeonggi-Do (KR)

(72) Inventors: Jung Bae KIM, Gwangju-Si, Gyeonggi-Do (KR); Won Suk SHIN, Gwangju-Si, Gyeonggi-Do (KR); Hyun Kyo SHIN, Gwangju-Si, Gyeonggi-Do (KR); Yong Hun LEE, Gwangju-Si, Gyeonggi-Do (KR); Chul Joo HWANG, Gwangju-Si, Gyeonggi-Do (KR)

(21) Appl. No.: 18/872,299

(22) PCT Filed: Jun. 5, 2023
(86) PCT No.: PCT/KR2023/007674

§ 371 Date: Dec. 6, 2024

(30) Foreign Application Priority Data
Jun. 7, 2022 (KR) 10-2022-0068954

(51) Int. Cl. H10F 77/20; H10F 10/19

(52) U.S. Cl. CPC H10F 77/215; H10F 10/19

(57) ABSTRACT

The present disclosure relates to a tandem solar cell, and more particularly, to a tandem solar cell in which a plurality of solar cells are electrically connected. The tandem solar cell in accordance with an exemplary embodiment of the present disclosure includes a first solar cell unit having a first upper electrode and a first lower electrode that are disposed spaced apart from each other, a second solar cell unit provided under the first solar cell unit and having a second upper electrode and a second lower electrode that are disposed spaced apart from each other, a first output terminal connected to the first upper electrode, a second output terminal connected to the second lower electrode, and a third output terminal connected to both the first lower electrode and the second upper electrode.

The present disclosure relates to a tandem solar cell, and more particularly, to a tandem solar cell in which a plurality of solar cells are electrically connected.

### BACKGROUND

A solar cell is a device that converts solar energy, that is, sunlight, into electric energy by using properties of a semiconductor and outputs the electric energy.

The solar cell has a P-N junction structure in which a P (positive) type semiconductor and an N (negative) type semiconductor are bonded together, and when sunlight is incident on the solar cell having the structure, holes and electrons are generated in the semiconductor by the energy of the incident light. In this case, by an electric field generated at the P-N junction, the holes move toward the P-type semiconductor and the electrons move toward the N-type semiconductor and thus an electric potential is generated, thereby generating electric energy, that is, electric power.

In recent years, in order to increase the efficiency of a solar cell, development of a tandem solar cell formed by stacking and electrically connecting a plurality of solar cells has been actively conducted. However, the tandem solar cell has a limitation that the light amount incident on each solar cell is different from the other, and current matching between the solar cells is very difficult, and as a result, the photoelectric conversion efficiency is low.

### PRIOR ART DOCUMENT

### Patent Document

(Patent Document 1) KR 10-2246070 B1

### SUMMARY

The present disclosure provides a tandem solar cell capable of utilizing an idle current generated from a plurality of solar cells.

In accordance with an exemplary embodiment, a tandem solar cell includes a first solar cell unit having a first upper electrode and a first lower electrode that are disposed spaced apart from each other, a second solar cell unit provided under the first solar cell unit and having a second upper electrode and a second lower electrode that are disposed spaced apart from each other, a first output terminal connected to the first upper electrode, a second output terminal connected to the second lower electrode, and a third output terminal connected to both the first lower electrode and the second upper electrode.

A first load may be connected between the first output terminal and the second output terminal, a second load may be connected between the first output terminal and the third output terminal, and a third load may be connected between the second output terminal and the third output terminal.

The tandem solar cell may further include a first current controller provided between the first output terminal and the third output terminal, a second current controller provided between the second output terminal and the third output terminal, and a controller configured to control operations of the first current controller and the second current controller.

The tandem solar cell may further include a first light amount sensor configured to detect a light amount of sunlight incident on the first solar cell unit and a second light amount sensor configured to detect a light amount of sunlight incident on the second solar cell unit, and the controller may be configured to selectively operate the first current controller and the second current controller according to the light amounts of sunlight detected by the first light amount sensor and the second light amount sensor.

The controller may be configured to operate the first current controller when the light amount detected by the first light amount sensor is greater than a preset first reference light amount or the light amount detected by the second light amount sensor is smaller than a preset second reference light amount and operate the second current controller when the light amount detected by the first light amount sensor is smaller than the first reference light amount or the light amount detected by the second light amount sensor is greater than the second reference light amount.

The tandem solar cell may further include a current sensor provided between the first output terminal and the second output terminal, and the controller may be configured to control operation of at least one of the first current controller and the second current controller according to an amount of current detected by the current sensor.

At least one of the first current controller and the second current controller may include a switch element.

The controller may be configured to switch the switch element in an off state to an on state when there is no change in the amount of current detected by the current sensor for a set time.

The controller may be configured to switch the switch element in the on state to the off state when the amount of current detected by the current sensor decreases after the switch element is switched to the on state.

At least one of the first current controller and the second current controller may include a variable resistance element.

The controller may be configured to reduce a resistance value of the variable resistance element set to a maximum resistance value when there is no change in the amount of current detected by the current sensor for a set time.

The controller may be configured to maintain the reduced resistance value of the variable resistance element when the amount of current detected by the current sensor decreases while reducing the resistance value of the variable resistance element.

The first solar cell unit may include a first transparent substrate for transmitting sunlight incident from above, and the second solar cell unit includes a second transparent substrate for transmitting sunlight incident from below.

The tandem solar cell may further include a bonding layer provided between the first lower electrode and the second upper electrode.

At least one of the first load, the second load, and the third load may include a secondary battery.

With a tandem solar cell in accordance with an exemplary embodiment, by including a third output terminal for supplying electric power to an auxiliary load, in addition to a first output terminal and a second output terminal for supplying electric power to a main load, an idle current generated by a difference in the amount of current generated from each solar cell may be additionally supplied to the auxiliary load.

### BRIEF DESCRIPTION OF THE DRAWINGS

FIG. 1 is a view schematically illustrating a tandem solar cell in accordance with an exemplary embodiment of the present disclosure;

FIGS. 2A and 2B illustrate a state in which a current controller is installed in accordance with an exemplary embodiment of the present disclosure;

FIG. 3 is a view illustrating a flow of current when sunlight of a reference light amount is incident on each of a first solar cell and a second solar cell;

FIG. 4 is a view illustrating a flow of current when sunlight of a light amount exceeding the reference light amount is incident on a first solar cell unit; and

FIG. 5 is a view illustrating a flow of current when sunlight of a light amount exceeding the reference light amount is incident on a second solar cell unit.

### DETAILED DESCRIPTION OF DISCLOSURE

Hereinafter, exemplary embodiments of the present disclosure will be described in detail with reference to the accompanying drawings. However, the present disclosure is not limited to the exemplary embodiments disclosed below, but will be implemented in a variety of different forms. The exemplary embodiments of the present disclosure are only provided to allow the present disclosure to be complete, and to completely inform those skilled in the art of the scope of the disclosure.

It will also be understood that when an element such as a layer, a region or a substrate is referred to as being “on” another one, it can be directly on the other one, intervening components may also be present.

Further, relative terms such as “above” or “under” may be used herein to describe a relative relationship of some elements to other elements as illustrated in the drawings. It will be understood that these relative terms are intended to encompass different orientations of the device in addition to the orientation depicted in the drawings. Here, the drawings may be exaggerated to describe the disclosure in detail, and like reference numerals refer to like elements in the drawings.

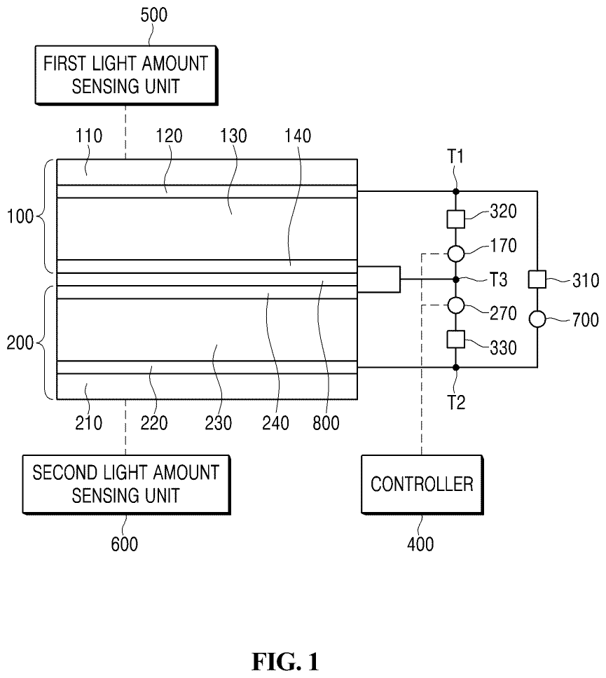

FIG. 1 is a view schematically illustrating a tandem solar cell in accordance with an exemplary embodiment of the present disclosure.

Referring to FIG. 1, the tandem solar cell in accordance with an exemplary embodiment includes a first solar cell unit 100 having a first upper electrode 120 and a first lower electrode 140 that are disposed spaced apart from each other, a second solar cell unit 200 provided under the first solar cell unit 100 and having a second upper electrode 240 and a second lower electrode 220 that are disposed spaced apart from each other, a first output terminal T1 connected to the first upper electrode 120, a second output terminal T2 connected to the second lower electrode 220, and a third output terminal T3 connected to both the first lower electrode 140 and the second upper electrode 240.

Here, a first load 310 may be connected between the first output terminal T1 and the second output terminal T2, a second load 320 may be connected between the first output terminal T1 and the third output terminal T3, and a third load 330 may be connected between the second output terminal T2 and the third output terminal T3.

The first solar cell unit 100 absorbs sunlight incident from above and converts the sunlight into electric energy. The first solar cell unit 100 may include a crystalline solar cell, an amorphous solar cell, a thin film solar cell, a dye-sensitized solar cell, an organic solar cell, a quantum dot solar cell, and a perovskite solar cell. Hereinafter, an exemplary structure will be described in which the first solar cell unit 100 includes a first substrate 110, the first upper electrode 120 provided below the first substrate 110, a first light absorbing layer 130 provided below the first upper electrode 120, and the first lower electrode 140 provided below the first light absorbing layer 130, but the structure is not limited thereto, and of course, may be applied to various types of known solar cells.

The first substrate 110 may include a transparent substrate for transmitting sunlight incident from above. When the first substrate 110 includes a transparent substrate, the first substrate 110 may be made of glass.

The first upper electrode 120 is provided under the first substrate 110. The first upper electrode 120 may be made of a transparent conductive material to transmit sunlight passing through the first substrate 110 to the first light absorbing layer 130 provided below the first upper electrode 120. Such a transparent conductive material may include a material having high light transmittance and excellent electrical conductivity, such as ZnO:Al, ZnO:B, or ZnO:Ga(GZO).

The first output terminal T1 may be provided to be connected to the first upper electrode 120. Such a first output terminal T1 may be electrically connected to the first upper electrode 120 by a conducting wire or line, and thus connected to one terminal of the first load 310 receiving electric power generated from the tandem solar cell. In this case, the first load 310 may include a secondary battery capable of storing electric power generated from the tandem solar cell and supplying the electric power to the outside, but is not limited thereto, and may include various electrical devices capable of receiving electric power generated from the tandem solar cell.

The first light absorbing layer 130 is provided below the first upper electrode 120. The first light absorbing layer 130 may be made of a silicon-based material such as amorphous silicon or crystalline silicon, but is not limited thereto, and of course, may be made of various materials that generate holes and electrons from incident sunlight.

For example, the first light absorbing layer 130 may be formed in an NIP structure including an N (negative) type semiconductor layer, a P (positive) type semiconductor layer, and an I (intrinsic) type semiconductor layer provided between the N type semiconductor layer and the P type semiconductor layer. When the light absorbing layer 115 is formed in the NIP structure in this way, the I type semiconductor layer may be depleted by the P type semiconductor layer and the N type semiconductor layer so that an electric field is generated therein, and thus holes and electrons generated by incident sunlight may be drifted by the electric field so that the holes and electrons are collected in the P type semiconductor layer and the N type semiconductor layer, respectively.

The first lower electrode 140 is provided below the first light absorbing layer 130. The first lower electrode 140 may be made of a transparent conductive material to transmit sunlight passing through the first light absorbing layer 130 or sunlight passing through the second solar cell unit 200 to be described below. As described above, such a transparent conductive material may include a material having high light transmittance and excellent electrical conductivity, such as ZnO:Al, ZnO:B, or ZnO:Ga(GZO).

The second solar cell unit 200 absorbs sunlight and converts the sunlight into electric energy. The second solar cell unit 200 may also include a crystalline solar cell, an amorphous solar cell, a thin film solar cell, a dye-sensitized solar cell, an organic solar cell, a quantum dot solar cell, a perovskite solar cell, and the like. Hereinafter, an exemplary structure will be described in which the second solar cell unit 200 includes a second substrate 210, the second lower electrode 220 provided above the second substrate 210, a second light absorbing layer 230 provided above the second lower electrode 220, and the second upper electrode 240 provided above the second light absorbing layer 230, but the structure is not limited thereto, and of course, may be applied to various types of known solar cells.

Here, the second solar cell unit 200 may absorb sunlight passing through the first solar cell unit 100 described above and convert the sunlight into electric energy, and may absorb sunlight incident from below and convert the sunlight into electric energy. That is, the tandem solar cell in accordance with an exemplary embodiment may be a one-sided light-receiving type tandem solar cell in which the second solar cell unit 200 absorbs sunlight passing through the first solar cell unit 100 and converts the sunlight into electric energy, or may be a double-sided light-receiving type tandem solar cell in which, together with the first solar cell unit 100 that absorbs sunlight incident from above and converts the sunlight into electric energy, the second solar cell unit 200 absorbs sunlight incident from below and converts the sunlight into electric energy.

The second substrate 210 may include an opaque substrate or a transparent substrate. That is, the second substrate 210 may include an opaque substrate for the one-sided light-receiving type, and may include a transparent substrate for the double-sided light-receiving type. However, of course, for the one-sided light receiving type, the second substrate 210 may include a transparent substrate. When the second substrate 210 includes a transparent substrate, the second substrate 210 may be made of glass to transmit sunlight incident from below.

The second lower electrode 220 is provided above the second substrate 210. In addition, the second light absorbing layer 230 may be provided above the second lower electrode 220 to absorb sunlight passing through the first solar cell unit 100 or to absorb sunlight incident from below and passing through the second substrate 210. In addition, the second upper electrode 240 may be provided above the second light absorbing layer 230, and structures of electrodes and light absorbing layers regarding the first solar cell unit 100 may be equally applied to those regarding the second lower electrode 220, the second light absorbing layer 230, and the second upper electrode 240, and thus repeated description thereof will be omitted.

The second output terminal T2 may be provided to be connected to the second lower electrode 220. Such a second output terminal T2 may be electrically connected to the second lower electrode 220 by a conducting wire or line, and thus connected to the other terminal of the first load 310 receiving electric power generated from the tandem solar cell.

The tandem solar cell in accordance with an exemplary embodiment may further include a bonding layer 800 for bonding the first solar cell unit 100 and the second solar cell unit 200. Such a bonding layer 800 may be provided between the second upper electrode 240 positioned on the upper side of the second solar cell unit 200 and the first lower electrode 140 positioned on the lower side of the first solar cell unit 100 so that the first solar cell unit 100 is stacked on and bonded to the second solar cell unit 200. The bonding layer 800 may include a light-transmitting material, and the light-transmitting material may include polyolefin elastomer (POE), a thermosetting resin, a light-curing resin, and the like.

Meanwhile, the second upper electrode 240 positioned on the upper side of the second solar cell unit 200 and the first lower electrode 140 positioned on the lower side of the first solar cell unit 100 may be electrically connected to each other. In this way, when the second upper electrode 240 and the first lower electrode 140 are electrically connected, the electric power generation efficiency of the solar cell may be improved, but since the first solar cell unit 100 and the second solar cell unit 200 are connected in series, current matching to match a current output from the first solar cell unit 100 and a current output from the second solar cell unit 200 is required.

For the current matching, the tandem solar cell in accordance with an exemplary embodiment may pattern at least one of the first light absorbing layer 130 and the second light absorbing layer 230 in a plurality of unit cells, and the second upper electrode 240 and the first lower electrode 140 may connect the unit cells obtained by the patterning of the first light absorbing layer 130 and unit cells obtained by the patterning of the second light absorbing layer 230 in a combination of a series structure and a parallel structure. For example, when sunlight of a first reference light amount is expected to be incident on the first solar cell unit 100 and sunlight of a second reference light amount is expected to be incident on the second solar cell unit 200, at least one of the first light absorbing layer 130 and the second light absorbing layer 230 may be patterned into a plurality of unit cells and the second upper electrode 240 and the first lower electrode 140 may connect the individual patterned unit cells in a combination of a series structure and a parallel structure, so that the current output from the first solar cell unit 100 when sunlight of the first reference light amount is incident and the current output from the second solar cell unit 200 when sunlight of the second reference light amount is incident have the same value.

As such, since at least one of the first light absorbing layer 130 and the second light absorbing layer 230 is patterned into a plurality of unit cells and the second upper electrode 240 and the first lower electrode 140 connect individual patterned unit cells in the combination of the series structure and the parallel structure, the first solar cell unit 100 and the second solar cell unit 200 may be matched in current when sunlight of the reference light amount is incident. However, when sunlight exceeding the reference light amount or less than the reference light amount is incident on at least one of the first solar cell unit 100 and the second solar cell unit 200, the current output from the first solar cell unit 100 and the current output from the second solar cell unit 200 are limited to a current having a relatively small value, and thus the photoelectric conversion efficiency of the tandem solar cell is reduced. When the tandem solar cell is a double-sided light-receiving type tandem solar cell in which, together with the first solar cell unit 100 that absorbs sunlight incident from above and converts the sunlight into electric energy, the second solar cell unit 200 absorbs solar light incident from below and converts the sunlight into electric energy, since it is almost impossible to maintain sunlight incident from above and the below at the reference light amount, the photoelectric conversion efficiency is reduced more seriously.

Therefore, in the tandem solar cell in accordance with an exemplary embodiment, the third output terminal T3 is formed to be connected to the first lower electrode 140 and the second upper electrode 240 in common, so that an idle current generated by a difference between the current output from the first solar cell unit 100 and the current output from the second solar cell unit 200 is utilized. To this end, the third output terminal T3 may be electrically connected to each of the first lower electrode 140 and the second upper electrode 240 by a conducting wire or line. When the third output terminal T3 is formed, the first output terminal T1 may be connected to one terminal of the second load 320 provided separately from the first load 310, and the third output terminal T3 may be connected to the other terminal of the second load 320. In addition, the third output terminal T3 may be connected to one terminal of the third load 330 provided separately from the first load 310, and the second output terminal T2 may be connected to the other terminal of the third load. In this case, the second load 320 and the third load 330 may include a secondary battery capable of storing electric power generated from the idle current and supplying the electric power to the outside, but is not limited thereto, and may include various electrical devices capable of receiving electric power generated from the idle current.

In addition, in order to maximize the idle current generated by the difference between the current output from the first solar cell unit 100 and the current output from the second solar cell unit 200, the tandem solar cell in accordance with an exemplary embodiment may further include a first current controller 170 provided between the first output terminal T1 and the third output terminal T3, a second current controller 270 provided between the second output terminal T2 and the third output terminal T3, and a controller 400 for controlling the operation of the first current controller 170 and the second current controller 270. The first current controller 170 and the second current controller 270 may include a switch element or a variable resistance element.

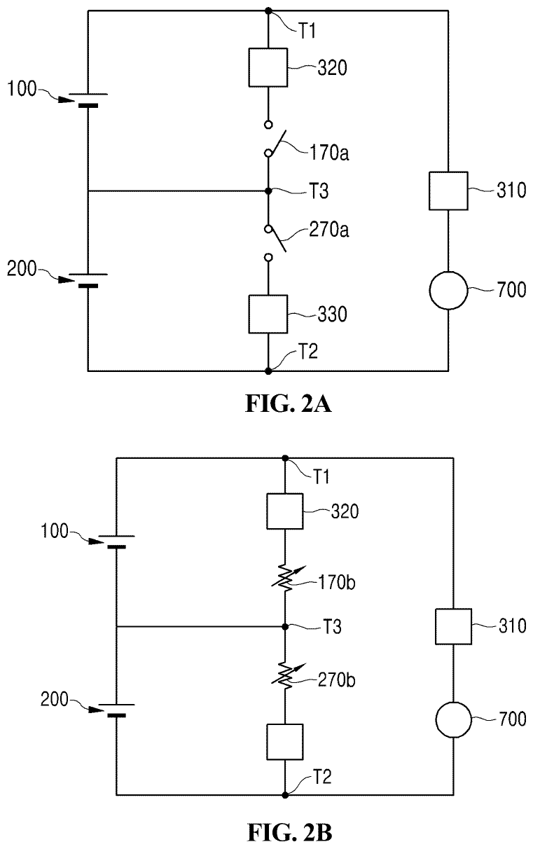

FIGS. 2A and 2B illustrate a state in which a current controller is installed in accordance with an exemplary embodiment of the present disclosure. Here, FIG. 2A is a view exemplarily illustrating a case in which the current controller includes a switch element, and FIG. 2B is a view exemplarily illustrating a case in which the current controller includes a variable resistance element.

Referring to FIG. 2A, the current controller may include a switch element. That is, at least one of the first current controller 170 and the second current controller 270 may include a switch element, and for example, the first current controller 170 may include a first switch element 170a, and the second current controller 270 may include a second switch element 270a. Here, the second load 320 and the first switch element 170a may be installed to be connected in series on a path electrically connecting the first output terminal T1 and the third output terminal T3, that is, in a conducting wire or line. In this case, the first switch element 170a may be set to an off state in which the path connecting the first output terminal T1 and the third output terminal T3 is disconnected, that is, opened. Then the first switch element 170a is operated in an on state in which the path connecting the first output terminal T1 and the third output terminal T3 is connected, that is, shorted, and the off state in which the path connecting the first output terminal T1 and the third output terminal T3 is disconnected, that is, opened, according to a command of the controller 400. Further, the third load 330 and the second switch element 270a may be installed to be connected in series on a path electrically connecting the third output terminal T3 and the second output terminal T2, that is, in a conducting wire or line. In this case, the second switch element 270a may also be set to an off state in which the path connecting the third output terminal T3 and the second output terminal T2 is disconnected, that is, opened. Then, the second switch element 270a is operated in an on state in which the path connecting the third output terminal T3 and the second output terminal T2 is connected, that is, shorted, and the off state in which the path connecting the third output terminal T3 and the second output terminal T2 is disconnected, that is, opened, according to a command of the controller 400.

Referring to FIG. 2B, the current controller may include a variable resistance element. That is, at least one of the first current controller 170 and the second current controller 270 may include a variable resistance element, and for example, the first current controller 170 may include a first variable resistance element 170b, and the second current controller 270 may include a second variable resistance element 270b. Here, the second load 320 and the first variable resistance element 170b may be installed to be connected in series on a path electrically connecting the first output terminal T1 and the third output terminal T3, that is, in a conducting wire or line. In this case, the first variable resistance element 170b may be set to have a maximum resistance value, and may be operated so that the resistance value is reduced according to a command of the controller 400. In addition, the third load 330 and the second variable resistance element 270b may be installed to be connected in series on a path electrically connecting the third output terminal T3 and the second output terminal T2, that is, in a conducting wire or line. In this case, the second variable resistance element 270b may also be set to have a maximum resistance value, and may be operated so that the resistance value is reduced according to a command of the controller 400.

In addition, the tandem solar cell in accordance with an exemplary embodiment may further include a first light amount sensor 500 for detecting a light amount of sunlight incident on the first solar cell unit 100 and a second light amount sensor 600 for detecting a light amount of sunlight incident on the second solar cell unit 200.

As described above, the tandem solar cell may be a double-sided light-receiving type tandem solar cell in which, together with the first solar cell unit 100 that absorbs sunlight incident from above and converts the sunlight into electric energy, the second solar cell unit 200 absorbs sunlight incident from below and converts the sunlight into electric energy. In this case, the first light amount sensor 500 may detect the light amount of sunlight incident from above, and the second light amount sensor 600 may detect the light amount of sunlight incident from below. However, the tandem solar cell is not limited thereto, and when the tandem solar cell is a one-sided light-receiving type tandem solar cell, the second light amount sensor 600 may detect the light amount absorbed by the second solar cell unit 200. The first light amount sensor 500 and the second light amount sensor 600 may include a sensor for detecting the light amount, and various well-known configurations for detecting the light amount may be applied to the sensor.

Meanwhile, the tandem solar cell in accordance with an exemplary embodiment may further include a current sensor 700 provided between the first output terminal T1 and the second output terminal T2.

Further, the current sensor 700 may be installed to be connected in series with the first load 310 on a path electrically connecting the first output terminal T1 and the second output terminal T2, that is, in a conducting wire or line. Accordingly, the current sensor 700 may measure an amount of current flowing along the path electrically connecting the first output terminal T1 and the second output terminal T2. The current sensor 700 may include a sensor for detecting current, and various well-known configurations for sensing current may be applied to the sensor.

As described above, the controller 400 controls operation of the first current controller 170 and the second current controller 270. In this case, the controller 400 may selectively operate the aforementioned first current controller 170 and second current controller 270 according to the light amount of sunlight detected by the first light amount sensor 500 and the second light amount sensor 600. In addition, the controller 400 may control operation of at least one of the aforementioned first current controller 170 and second current controller 270 according to the amount of current detected by the current sensor 700.

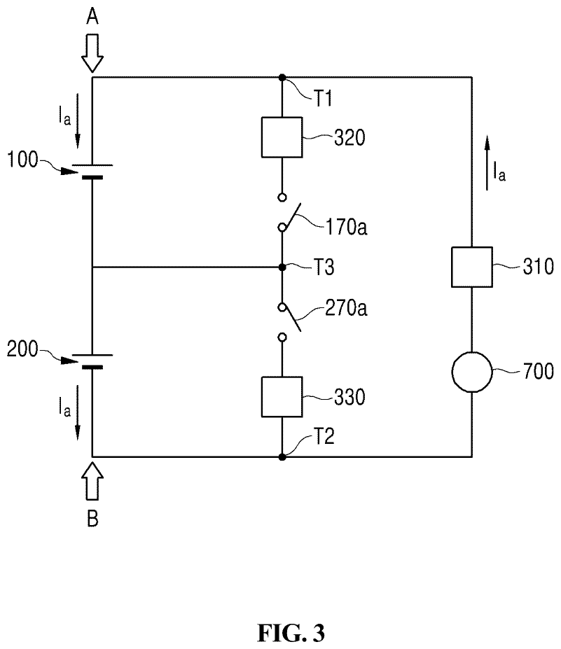

Hereinafter, with reference to FIGS. 3 to 5, details of the controller 400 controlling the operation of the first current controller 170 and the second current controller 270 will be described.

FIG. 3 is a view illustrating a flow of current when sunlight of a reference light amount is incident on each of the first solar cell and the second solar cell.

In the tandem solar cell in accordance with an exemplary embodiment, a case is set in which sunlight of a first reference light amount A is incident on the first solar cell unit 100 and sunlight of a second reference light amount B is incident on the second solar cell unit 200, and the first solar cell unit 100 and the second solar cell unit 200 are matched in current.

When the light amount detected by the first light amount sensor 500 has the same value as the preset first reference light amount A and the light amount detected by the second light amount sensor 600 has the same value as the preset second reference light amount B, a current (Iₐ) output from the first solar cell unit 100 and a current (Iₐ) output from the second solar cell unit 200 have the same amount of current, and thus an idle current is not generated.

Accordingly, the controller 400 does not operate the first switch element 170a and the second switch element 270a. As described above, the first switch element 170a is initially set to the off state in which the path connecting the first output terminal T1 and the third output terminal T3 is opened, and the second switch element 270a is also initially set to the off state in which the path connecting the third output terminal T3 and the second output terminal T2 is opened. Accordingly, all of the currents (Iₐ) output from the first solar cell unit 100 and the second solar cell unit 200 are supplied to the first load 310, and not suppled to the second load 320 and the third load 330.

Although not illustrated, the first current controller 170 and the second current controller 270 may include the first variable resistance element 170b and the second variable resistance element 270b, respectively. Even in this case, the controller 400 does not operate the first variable resistance element 170b and the second variable resistance element 270b. As described above, the first variable resistance element 170b is initially set to have the maximum resistance value, and the second variable resistance element 270b is also initially set to have the maximum resistance value. Accordingly, most of the currents (Iₐ) output from the first solar cell unit 100 and the second solar cell unit 200 are supplied to the first load 310, and almost no current is supplied to the second load 320 and the third load 330.

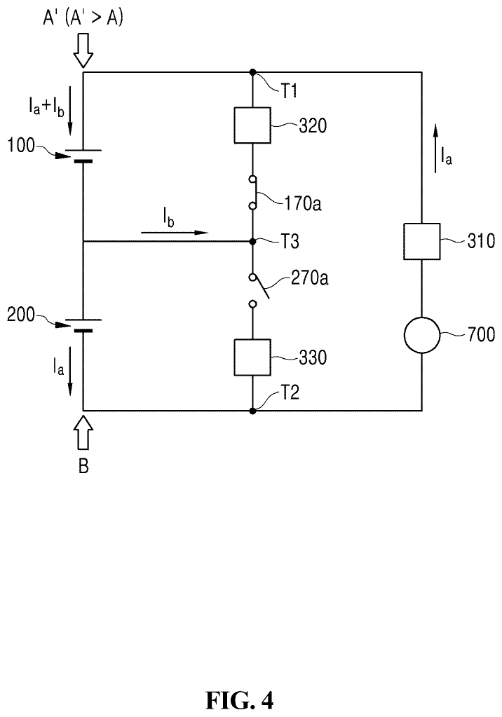

FIG. 4 is a view illustrating a flow of current when sunlight of a light amount exceeding the reference light amount is incident on the first solar cell unit.

When the light amount detected by the first light amount sensor 500 is greater than the preset first reference light amount A (A′>A) and the light amount detected by the second light amount sensor 600 has the same value as the preset second reference light amount B, the current (Iₐ+I_{b}) output from the first solar cell unit 100 has the amount of current greater than the current (Iₐ) output from the second solar cell unit 200, and thus the idle current is generated. This is equally applied when the light amount detected by the first light amount sensor 500 is equal to the preset first reference light amount A, and the light amount detected by the second light amount sensor 600 is smaller than a preset second reference light amount B (B′<B), or the rate of increase in the light amount detected by the first light amount sensor 500 is greater than the rate of increase in the light amount detected by the second light amount sensor 600, or even when the rate of decrease in the light amount detected by the first light amount sensor 500 is smaller than the rate of decrease in the light amount detected by the second light amount sensor 600.

In this case, the controller 400 operates only the first switch element 170a and does not operate the second switch element 270a. As described above, since the second switch element 270a is initially set to the off state in which the path connecting the third output terminal T3 and the second output terminal T2 is opened, current is not supplied to the third load 330.

In this case, in operating the first switch element 170a, the controller 400 controls the operation of the first switch element 170a according to the amount of current detected by the current sensor 700. That is, the first switch element 170a is initially set to the off state in which the path connecting the first output terminal T1 and the third output terminal T3 is opened. Here, the controller 400 switches the first switch element 170a in the off state to the on state when there is no change in the amount of current detected by the current sensor 700 for a set time. Then, the controller 400 switches the first switch element 170a in the on state to the off state when the amount of current detected by the current sensor 700 decreases after the first switch element 170a is switched to the on state.

That is, even when the light amount detected by the first light amount sensor 500 is greater than the preset first reference light amount A (A′>A) and the light amount detected by the second light amount sensor 600 has the same value as the preset second reference light amount B, there is no change in the amount of current detected by the current sensor 700 because the first solar cell unit 100 and the second solar cell unit 200 are connected in series. However, when there is no change in the amount of current detected by the current sensor 700 for the set time despite the difference in the light amount detected, the controller 400 supplies an idle current (I_{b}) to the second load 320 by switching the first switch element 170a from the off state to the on state. In this case, since the second load 320 and the first switch element 170a have a low resistance value, a current having a larger amount of current than the idle current (I_{b}) is supplied to the second load 320, which may result in the decrease in the amount of current supplied to the first load 310. In this case, the controller 400 switches the first switch element 170a to the off state when the amount of current detected by the current sensor 700 decreases after the first switch element 170a is switched to the on state. In this way, a constant current is supplied to the first load 310 again, and the controller 400 switches the first switch element 170a from the off state to the on state when there is no change in the amount of current detected by the current sensor 700 for the set time. Therefore, the first switch element 170a is continuously switched between the off state and the on state, and thus current may be intermittently supplied to the second load 320 when the first switch element 170a is in the on state.

Although not illustrated, the first current controller 170 and the second current controller 270 may include the first variable resistance element 170b and the second variable resistance element 270b, respectively. Even in this case, the controller 400 operates only the first variable resistance element 170b and does not operate the second variable resistance element 270b. As described above, since the second variable resistance element 270b is initially set to have a maximum resistance value, almost no current is supplied to the third load 330.

In this case, in operating the first variable resistance element 170b, the controller 400 controls the operation of the first variable resistance element 170b according to the amount of current detected by the current sensor 700. That is, the first variable resistance element 170b is initially set to have a maximum resistance value. Here, the controller 400 gradually reduces the resistance value of the first variable resistance element 170b set to the maximum resistance value when there is no change in the amount of current detected by the current sensor 700 for the set time. Then, when the amount of current detected by the current sensor 700 decreases while the resistance value of the first variable resistance element 170b is reduced, the controller 400 maintains the resistance value of the first variable resistance element 170b in a reduced state.

That is, even when the light amount detected by the first light amount sensor 500 is greater than the preset first reference light amount A (A′>A) and the light amount detected by the second light amount sensor 600 has the same value as the preset second reference light amount B, there is no change in the amount of current detected by the current sensor 700 because the first solar cell unit 100 and the second solar cell unit 200 are connected in series. However, when there is no change in the amount of current detected by the current sensor 700 for the set time despite the difference in the light amount detected, the controller 400 supplies the idle current (I_{b}) to the second load 320 by reducing the resistance value of the first variable resistance element 170b. At this time, since the first variable resistance element 170b is initially set to the maximum resistance value, a current having a smaller amount of current than the idle current (I_{b}) is supplied to the second load 320, and there may be no change in the current amount supplied to the first load 310. In this case, when the amount of current detected by the current sensor 700 decreases after the resistance value of the first variable resistance element 170b is continuously reduced, the controller 400 maintains the resistance value of the first variable resistance element 170b. In this way, the idle current (I_{b}) corresponding to the difference between the current (Iₐ+I_{b}) output from the first solar cell unit 100 and the current (Iₐ) output from the second solar cell unit 200 may be supplied to the second load 320 as it is.

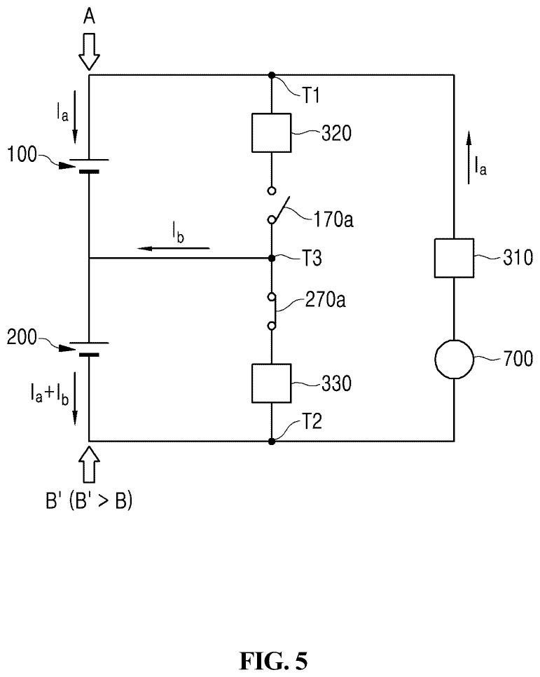

FIG. 5 is a view illustrating a flow of current when sunlight of a light amount exceeding the reference light amount is incident on the second solar cell unit.

When the light amount detected by the first light amount sensor 500 has the same value as the preset first reference light amount A and the light amount detected by the second light amount sensor 600 is greater than the preset second reference light amount B (B′>B), the current (Iₐ+I_{b}) output from the second solar cell unit 200 has the amount of current greater than the current (Iₐ) output from the first solar cell unit 100, and thus the idle current is generated. This is equally applied when the light amount detected by the first light amount sensor 500 is smaller than the preset first reference light amount A (A′<A), and the light amount detected by the second light amount sensor 600 is equal to the preset second reference light amount B, or the rate of increase in the light amount detected by the first light amount sensor 500 is smaller than the rate of increase in the light amount detected by the second light amount sensor 600, or even when the rate of decrease in the light amount detected by the first light amount sensor 500 is greater than the rate of decrease in the light amount detected by the second light amount sensor 600.

In this case, the controller 400 operates only the second switch element 270a and does not operate the first switch element 170a. As described above, since the first switch element 170a is initially set to the off state in which the path connecting the first output terminal T1 and the third output terminal T3 is opened, current is not supplied to the second load 320.

In this case, in operating the second switch element 270a, the controller 400 controls the operation of the second switch element 270a according to the amount of current detected by the current sensor 700. That is, the second switch element 270a is initially set to the off state in which the path connecting the third output terminal T3 and the second output terminal T2 is opened. Here, the controller 400 switches the second switch element 270a in the off state to the on state when there is no change in the amount of current detected by the current sensor 700 for a set time. Then, the controller 400 switches the second switch element 270a in the on state to the off state when the amount of current detected by the current sensor 700 decreases after the second switch element 270a is switched to the on state.

That is, even when the light amount detected by the first light amount sensor 500 has the same value as the preset first reference light amount A and the light amount detected by the second light amount sensor 600 is greater than the preset second reference light amount B (B′>B), there is no change in the amount of current detected by the current sensor 700 because the first solar cell unit 100 and the second solar cell unit 200 are connected in series. However, when there is no change in the amount of current detected by the current sensor 700 for the set time despite the difference in the light amount detected, the controller 400 supplies an idle current (I_{b}) to the third load 330 by switching the second switch element 270a from the off state to the on state. In this case, since the third load 330 and the second switch element 270a have a low resistance value, a current having a larger amount of current than the idle current (I_{b}) is supplied to the third load 330, which may result in the decrease in the amount of current supplied to the first load 310. In this case, the controller 400 switches the second switch element 270a to the off state when the amount of current detected by the current sensor 700 decreases after the second switch element 270a is switched to the on state. In this way, a constant current is supplied to the first load 310 again, and the controller 400 switches the second switch element 270a from the off state to the on state when there is no change in the amount of current detected by the current sensor 700 for the set time. Therefore, the second switch element 270a is continuously switched between the off state and the on state, and thus current may be intermittently supplied to the third load 330 when the second switch element 270a is in the on state.

Although not illustrated, the first current controller 170 and the second current controller 270 may include the first variable resistance element 170b and the second variable resistance element 270b, respectively. Even in this case, the controller 400 operates only the second variable resistance element 270b and does not operate the first variable resistance element 170b. As described above, since the first variable resistance element 170b is initially set to have a maximum resistance value, almost no current is supplied to the second load 320.

In this case, in operating the second variable resistance element 270b, the controller 400 controls the operation of the second variable resistance element 270b according to the amount of current detected by the current sensor 700. That is, the second variable resistance element 270b is initially set to have a maximum resistance value. Here, the controller 400 gradually reduces the resistance value of the second variable resistance element 270b set to the maximum resistance value when there is no change in the amount of current detected by the current sensor 700 for the set time. Then, when the amount of current detected by the current sensor 700 decreases while the resistance value of the second variable resistance element 270b is reduced, the controller 400 maintains the resistance value of the second variable resistance element 270b in a reduced state.

That is, even when the light amount detected by the first light amount sensor 500 has the same value as the preset first reference light amount A and the light amount detected by the second light amount sensor 600 is greater than the preset second reference light amount B (B′>B), there is no change in the amount of current detected by the current sensor 700 because the first solar cell unit 100 and the second solar cell unit 200 are connected in series. However, when there is no change in the amount of current detected by the current sensor 700 for the set time despite the difference in the light amount detected, the controller 400 supplies the idle current (I_{b}) to the third load 330 by reducing the resistance value of the second variable resistance element 270b. At this time, since the second variable resistance element 270b is initially set to the maximum resistance value, a current having a smaller amount of current than the idle current (I_{b}) is supplied to the third load 330, and there may be no change in the current amount supplied to the first load 310. In this case, when the amount of current detected by the current sensor 700 decreases after the resistance value of the second variable resistance element 270b is continuously reduced, the controller 400 maintains the resistance value of the second variable resistance element 270b. In this way, the idle current (I_{b}) corresponding to the difference between the current (Iₐ+I_{b}) output from the first solar cell unit 100 and the current (Iₐ) output from the second solar cell unit 200 may be supplied to the third load 330 as it is.

As described above, with the tandem solar cell in accordance with an exemplary embodiment, by including the third output terminal for supplying electric power to an auxiliary load, in addition to the first output terminal and the second output terminal for supplying electric power to a main load, the idle current generated by a difference in the amount of current generated from each solar cell may be additionally supplied to the auxiliary load.

In the above, although preferred embodiments of the present disclosure have been described and illustrated using specific terms, such terms are only used to clearly describe the present disclosure, and it is obvious that various modifications and changes can be made to the exemplary embodiments of the present disclosure and the described terms without departing from the spirit and scope of the present disclosure as defined by the following claims and their equivalents. Such modified embodiments should not be individually understood from the spirit and scope of the present disclosure, and should be construed as falling within the scope of the claims of the present disclosure.

What is claimed is:

1. A tandem solar cell comprising:
a first solar cell unit having a first upper electrode and a first lower electrode that are disposed spaced apart from each other;
a second solar cell unit provided under the first solar cell unit and having a second upper electrode and a second lower electrode that are disposed spaced apart from each other;
a first output terminal connected to the first upper electrode;
a second output terminal connected to the second lower electrode; and
a third output terminal connected to both the first lower electrode and the second upper electrode.

2. The tandem solar cell of claim 1, wherein a first load is connected between the first output terminal and the second output terminal,
a second load is connected between the first output terminal and the third output terminal, and
a third load is connected between the second output terminal and the third output terminal.

3. The tandem solar cell of claim 1, further comprising:
a first current controller provided between the first output terminal and the third output terminal;
a second current controller provided between the second output terminal and the third output terminal, and
a controller configured to control operations of the first current controller and the second current controller.

4. The tandem solar cell of claim 3, further comprising:
a first light amount sensor configured to detect a light amount of sunlight incident on the first solar cell unit; and
a second light amount sensor configured to detect a light amount of sunlight incident on the second solar cell unit,
wherein the controller is configured to selectively operate the first current controller and the second current controller according to the light amounts of sunlight detected by the first light amount sensor and the second light amount sensor.

5. The tandem solar cell of claim 4, wherein the controller is configured to:
operate the first current controller when the light amount detected by the first light amount sensor is greater than a preset first reference light amount or the light amount detected by the second light amount sensor is smaller than a preset second reference light amount; and
operate the second current controller when the light amount detected by the first light amount sensor is smaller than the first reference light amount or the light amount detected by the second light amount sensor is greater than the second reference light amount.

6. The tandem solar cell of claim 3, further comprising a current sensor provided between the first output terminal and the second output terminal,
wherein the controller is configured to control operation of at least one of the first current controller and the second current controller according to an amount of current detected by the current sensor.

7. The tandem solar cell of claim 6, wherein at least one of the first current controller and the second current controller includes a switch element.

8. The tandem solar cell of claim 7, wherein the controller is configured to switch the switch element in an off state to an on state when there is no change in the amount of current detected by the current sensor for a set time.

9. The tandem solar cell of claim 8, wherein the controller is configured to switch the switch element in the on state to the off state when the amount of current detected by the current sensor decreases after the switch element is switched to the on state.

10. The tandem solar cell of claim 6, wherein at least one of the first current controller and the second current controller includes a variable resistance element.

11. The tandem solar cell of claim 10, wherein the controller is configured to reduce a resistance value of the variable resistance element set to a maximum resistance value when there is no change in the amount of current detected by the current sensor for a set time.

12. The tandem solar cell of claim 11, wherein the controller is configured to maintain the reduced resistance value of the variable resistance element when the amount of current detected by the current sensor decreases while reducing the resistance value of the variable resistance element.

13. The tandem solar cell of claim 1, wherein:
the first solar cell unit includes a first transparent substrate for transmitting sunlight incident from above, and
the second solar cell unit includes a second transparent substrate for transmitting sunlight incident from below.

14. The tandem solar cell of claim 1, further comprising a bonding layer provided between the first lower electrode and the second upper electrode.

15. The tandem solar cell of claim 2, wherein at least one of the first load, the second load, and the third load includes a secondary battery.
